(19) United States
(12) Patent Application Publication
(10) Pub. No.: US 2011/0181667 A1
(43) Pub. Date: Jul. 28, 2011

(54) INKJET HEAD AND METHOD FOR MANUFACTURING THE SAME

(75) Inventors: Tomoyuki Sagara, Osaka (JP); Hiroe Takatani, Osaka (JP)

(73) Assignee: SHARP KABUSHIKI KAISHA, Osaka (JP)

(21) Appl. No.: 12/671,337

(22) PCT Filed: Jul. 31, 2008
(86) PCT No.: PCT/JP2008/063762

§ 371 Date: Jun. 28, 2010

(30) Foreign Application Priority Data
Aug. 1, 2007 (JP) 2007-200639

(51) Int. Cl. B41J 2/045; H01L 41/22

(52) U.S. Cl. 347/68; 29/25.35

(57) ABSTRACT

There is provided an inkjet head that permits ink to be easily circulated therein and that is applicable to the ink containing fine particles, without making a structure thereof complicated. The inkjet head 25 has a piezoelectric substrate 1, a nozzle plate 21, and a manifold 11. The piezoelectric substrate 1 has a plurality of ink grooves 41, on a top surface thereof, which are separated from one another by partition walls 3 and which are provided with electrodes on inner walls of the grooves. The piezoelectric substrate 1 is accommodated in a recess 11u on a top surface of the manifold 11 so as to form a first common ink groove 5 and a second common ink groove 6. The nozzle plate 21 covers upper side of the plurality of ink grooves 41 so as to define the plurality of separated ink chambers 2, and covers top faces of the first common ink groove 5 and the second common ink groove 6 so as to define a first common ink chamber 5i and a second common ink chamber 6i.

### TECHNICAL FIELD

The present invention relates to an inkjet head for use in a printer or the like, for instance, and to a method for manufacturing the same.

### BACKGROUND ART

For printers, in recent years, nonimpact printers such as of inkjet type, which easily address transition to color printers and multiple levels of halftone, have rapidly and increasingly been becoming common in place of impact printers. Among inkjet heads that are used as ink jetting devices therein, in particular, inkjet heads of drop-on-demand type that jet only ink droplets required for printing have been receiving attentions in terms of satisfactory efficiency of jetting, easiness of cost reduction and the like. In the drop-on-demand type have become dominant Kyser type, thermal jet type and the like.

The Kyser type, however, has defects of difficulty in size reduction and unsuitability for density increase. Though the thermal jet type is suitable for the density increase, the type has problems in that formation of bubbles in ink by heating of the ink using a heater and jetting with use of energy of the bubbles require heat resistance of the ink and make it difficult to extend a life of the heater and in that poor energy efficiency results in increase in power consumption.

As a solution to such defects of the above types, there has been proposed an inkjet technique using share mode deformation of piezoelectric material. The technique is suitable for increase in density of nozzles, reduction in power consumption, and higher drive frequency because electrodes formed on both side surfaces of ink channel walls (which will be referred to as “channel walls”) composed of piezoelectric material are used to form electric fields in a direction orthogonal to a direction of polarization of the piezoelectric material so as to deform the channel walls in share mode, and because change in pressure wave that is caused by the deformation is used to discharge ink droplets.

Recently, inkjet heads using the share mode deformation have been beginning to be extensively employed in industrial applications. For instance, there have been being developed such applications as drawing of interconnections by discharge of conductive material as ink, production of color filters by discharge of ink with colors R (Red), G (Green) and B (Blue), production of three-dimensional structures such as microlens and spacers by discharge of thermosetting ink or ultraviolet (UV) curing ink.

In industrial applications, in particular, there have been emerging demands for decrease in nozzle density, caused by increase in size of liquid crystal screens, as well as demands for the increase in nozzle density allowing discharge with high definition. In comparison between use of inkjet heads in industrial applications and use thereof for printers as consumer appliances, severity in required accuracy can be cited as a difference therebetween. The inkjet heads in industrial applications are required to operate in far severer accuracy than the inkjet heads for consumer appliances. In industrial applications are demanded impact of a specified quantity of droplets on a specified address and thus severe control over accuracy of the impact and the quantity of droplets. Therefore, an event in which some trouble disturbs discharge through an ink channel, which is to be essentially dischargeable, in an inkjet head causes a serious problem when the inkjet head is used in industrial applications, even if an incidence of the event is on an insignificant level in applications for consumers.

With such development of applications of inkjet in various fields, an increasingly wide variety of types of ink have been used. For instance, there can be enumerated highly volatile ink containing organic solvent, strongly acid or alkaline ink, ink containing pigment, resin components or the like, ink containing fine particles such as beads, composites of the mentioned ink, and the like. In particular, the ink containing fine particles such as beads entails a fear that a difference in specific gravity between solvent of the ink and the contained fine particles may cause precipitation and flotage of the fine particles and uneven distribution of concentrations of the fine particles in the ink. The uneven distribution causes a variation in number of fine particles contained in each droplet being discharged and thus may cause deterioration in performance of products and occurrence of defective products. In order to avoid such situation, it is necessary to prevent precipitation of the fine particles by circulation and agitation of the ink in an ink tank and the inkjet head. In order to ensure discharge with stabilization of the number of fine particles contained in each droplet being discharged, strictly, it is important to perform the above circulation and agitation of the ink also at the moment when the ink resides in immediate vicinity of nozzle holes.

A technique for ensuring circulation and agitation of ink up to immediate vicinity of nozzle holes has been disclosed in WO 95/31335. In an inkjet head shown in FIGS. 2 and 3 of WO95/31335, pressure generation chambers define spaces wherein a nozzle plate having nozzle holes is placed on front side thereof and a vibration plate is placed on rear side thereof. Two common ink chambers are placed on both sides of the pressure generation chambers so that the pressure generation chambers are interposed therebetween, and the two common ink chambers communicate with the pressure generation chambers. This device has a structure in which ink can be supplied via the pressure generation chambers from one common ink chamber to the other common ink chamber. In the inkjet head, the pressure generation chambers having the nozzle holes form passages for ink, so that the ink can be circulated up to immediate vicinity of the nozzle holes. In FIG. 4 of WO 95/31335 is shown a recorder including the inkjet head, as a whole. In the recorder, a subtank is replenished with ink via the inkjet head from an ink cartridge, while the ink can be returned from the subtank via the inkjet head into the ink cartridge with use of a head difference. In the recorder of WO 95/31335, ink is circulated in this manner.

In an inkjet head disclosed in JP 2006-142509 A, two common ink chambers are provided as two grooves being parallel to each other on a surface of a piezoelectric substrate. A large number of groove-like ink chambers are provided so as to be interposed between the two common ink chambers and so as to communicate with both the two common ink chambers. In JP 2006-142509 A is proposed the inkjet head that makes use of share mode deformation of piezoelectric material of wall parts of the groove-like ink chambers.

One type of inkjet head is called laminated type. A structure of the inkjet head is constructed by lamination of members with alignment thereof, and an example thereof is disclosed in JP 6-183029 A.

### SUMMARY OF INVENTION

### Technical Problem

In the recorder disclosed in WO 95/31335, as described above, ink is supplied via the pressure generation chambers from one common ink chamber to the other common ink chamber in middle of flow of the ink between the ink cartridge and the subtank, so that the ink can be circulated up to immediate vicinity of the nozzle holes; however, the inkjet head has a defect in that the head is of the laminated type.

As described in JP 6-183029 A, an inkjet head of laminated type is composed of five members, i.e., a vibrating element unit having vibrating elements mounted on a substrate, a flow path forming member, a vibrating plate forming member, a spacer for forming gaps that are to make pressure producing chambers, and a nozzle plate having nozzle holes, and is constructed by alignment and lamination of the members. For achievement of the impact accuracy and discharge performance with small variation in the inkjet head, accuracy of relative positions of the nozzle holes and driving parts is extremely important, and centers of the nozzle holes and centers of ink passages in the driving parts are required to be placed in alignment. Accordingly, alignment with high accuracy is demanded for each of the five members. In order to produce the one inkjet head, it is necessary to repeat such accurate alignment four times. This entails extremely troublesome works. The inkjet head of JP 6-183029 A is unsuitable for size reduction in that laminar piezoelectric elements are used therein for ensuring a quantity of displacement and in that the inkjet head is composed of a large number of components. Such troublesome assembling works and the large number of components lead to an increase in cost of the inkjet head.

As an example of non-laminar type inkjet head, by contrast, the share-mode type inkjet head 126 disclosed in JP 2006-142509 A will be described with reference to FIGS. 15 and 16. Reference numerals and designations of components in the drawings are not necessarily as referred to in JP 2006-142509 A.

As shown in FIG. 15, the inkjet head 126 is constructed by installation of a piezoelectric substrate 101 in a manifold 111 having an elliptical recess and by covering thereof with a nozzle plate 21 having a plurality of nozzle holes 20. On a top surface of the piezoelectric substrate 101 are provided two wide shallow grooves that are to form common ink chambers 105, 106 and that are parallel to each other. A large number of narrow deep grooves are provided so as to link the two grooves. The narrow deep grooves are covered with the nozzle plate 21 on upper side thereof so as to form separated ink chambers 102 as shown in FIG. 16. FIG. 16 is a sectional view taken along a line XVI-XVI in FIG. 15. To underside of the manifold 111 are connected ink supply pipes 112, 113. In each of the common ink chambers 105, 106, one end communicates with a nipple opening 114 and the other end communicates with a nipple opening 115. The nipple openings 114, 115 correspond to both ends of the elliptical recess and communicate with the ink supply pipes 112, 113, respectively.

The inkjet head 126 is easy to assemble and suitable for size reduction because the inkjet head is composed of a small number of components and because accurate alignment in assembly is required only in a step of bonding the piezoelectric substrate 101 having the channel grooves thereon, which are to form the separated ink chambers 102, onto the nozzle plate 21 having the nozzle holes 20.

On an assumption that the inkjet head 126 circulates ink therein so as to supply the ink from the ink supply pipe 112 to the nipple opening 114 and so as to recover extra ink from the nipple opening 115 through the ink supply pipe 113, the ink moving from the nipple opening 114 to the nipple opening 115 separate and pass through two routes in general, i.e., through the common ink chambers 105 and 106 as shown by arrows 35 in FIG. 15. In this process, a resistance of a flow passage with turns on the way and shuttling between the common ink chambers 105, 106 via the separated ink chambers 102 apparently exceeds a resistance of a flow passage only through either one of the common ink chambers 105, 106 without such shuttling. Therefore, much of the ink travels directly from the nipple opening 114 to the nipple opening 115 through only one of the common ink chambers 105, 106. The nozzle holes 20, which are not opened in the common ink chambers 105, 106 but are opened in middle of the separated ink chambers 102, cause a problem in that it is impossible to positively circulate the ink in the separated ink chambers 102 that are spaces in immediate vicinity of the nozzle holes 20.

In the inkjet head 126, the common ink chambers 105 and 106 have to be formed with a depth smaller to a given or greater extent than depths of the separated ink chambers 102 so as not to interrupt conduction between an electrode formed on inner wall surfaces of each separated ink chamber 102 and electrodes formed on inner wall surfaces of shallow groove portions provided in connection with both ends of each separated ink chamber 102. That is, there is a restriction in that the depth of the common ink chambers 105 and 106 in the inkjet head 126 cannot be larger than the depths of the separated ink chambers 102 formed in the piezoelectric substrate 101.

In order to promote flow of ink via the separated ink chambers 102 in the inkjet head 126, preferably, a flow passage resistance of the common ink chambers 105, 106 is sufficiently smaller than a flow passage resistance of the separated ink chambers 102 and is ignorable. In a qualitative expression, the smaller a sectional area of a flow passage and the larger a length of the flow passage, the larger a resistance of the flow passage. Therefore, the inkjet head 126 is disadvantageous due to the restriction on at least the depth of the common ink chambers 105, 106 that must be smaller to a given or greater extent than the depths of the ink chambers 102, even if overall dimensions (external sizes and thickness of the substrate) are appropriately selected. This is a problem that becomes serious especially on condition that increase in the dimensions of the inkjet head 126 results in elongation of the flow passages.

Increasing sectional areas of the common ink chambers 105, 106 by increasing widths thereof for decreasing the flow passage resistances of the common ink chambers 105, 106 necessitates increasing size of the individual piezoelectric substrate 101 and interferes with size reduction. The increase in the size of the piezoelectric substrate 101 leads to increase in cost in terms of material cost.

The separated ink chambers 102 in the inkjet head 126 are connected to the shallow groove portions forming external connection terminals, at both ends of the piezoelectric substrate 101, and the shallow groove portions open on both end faces of the piezoelectric substrate 101. Such machining of the separated ink chambers 102 and the shallow groove portions can be performed by a machining method with use of vertical movement of a dicing blade, i.e., by so-called chopper machining. So-called “R shape” (i.e., rounded shape) of the groove portions results from transfer of an external shape of the dicing blade. With machining of the rounded shape that links the greatest depth and the shallow groove portions of the separated ink chamber 102, the common ink chambers 105, 106 are normally positioned in middle of the portions having the rounded shape. Then depths of the separated ink chambers 102 in positions where the common ink chambers 105, 106 and the separated ink chambers 102 cross are not the greatest but shallower than the depth to a certain extent. In order to ensure the conduction between the electrode formed on the inner wall surfaces of each separated ink chamber 102 and the electrodes formed on the inner wall surfaces of the shallow groove portions as described above, accordingly, it is necessary to set the depths of the common ink chambers 105, 106 further shallower, and thus the flow passage resistance of the common ink chambers 105, 106 cannot be reduced.

In such a configuration in which the rounded portions with the groove depths gradually decreasing are formed by the transfer of the shape of outside diameter of the dicing blade to portions of ink grooves with chopper machining using the vertical movement of the dicing blade 30 and in which the shallow groove portions for forming the external connection terminals are formed in connection with the rounded portions, the deeper driving portions of the ink grooves and the shallower the shallow groove portions, the larger lengths of the rounded portions. The larger the outside diameter of the dicing blade, the larger the lengths of the rounded portions. Eventually, the lengths have a great influence on number (what is called “yield per wafer”) of the inkjet heads that can be obtained from one wafer-like piezoelectric substrate.

On assumptions of the depth of the ink grooves of 240 μm, the depth of the shallow groove portions of 5 μm, and the outside diameter of the blade of 25.4 mm, an area L to which the shape of the outside diameter of the blade is transferred is calculated by the following equation.

L=\sqrt{25.4²−(25.4−0.24)²}

L=3.48 mm [Equation 1]

A length of an area required for discharge from the inkjet head is assumed to be 3 mm. On further assumptions that the whole shallow groove portions are formed as the external connection terminals and that a length of the external connection terminals is 1 mm, a length of the inkjet head in a longitudinal direction of the ink grooves is 3.48+3+1=7.48 mm.

In this configuration, a proportion of the lengths of the rounded portions in the overall length of the one inkjet head is as follows.

(3.48+1)/7.48*100=about 60%

That is, the portions making no contribution to the discharge of ink make up about 60%.

Hereinbelow consideration will be given to ink circulation in the inkjet head 126 using a head difference in accordance with teachings of WO 95/31335. It is desirable to determine the head difference from a flow rate allowing the ink circulation without precipitation and a flow passage resistance of the inkjet head 126, which resistance is made up of the flow passage resistances of the common ink chambers 105, 106 and the separated ink chambers 102, and the resistances having large values necessitate setting an extremely large head difference. Provided that achievement of satisfactory circulation is aimed at only with such increase in the head difference, it may be impossible to simply increase the head difference in terms of configuration of the device. Therefore, the actual device cannot help being configured so that the head difference may be within a range which can be attained within constraint on the configuration of the device. On condition that a flow rate, which is the head difference divided by the flow passage resistance, is smaller than the flow rate allowing the ink circulation without precipitation, insufficient ink circulation results in precipitation of fine particles. Consequently, the inkjet head 126 has a problem in that it may be impossible for the head to discharge droplets with stabilization of number of fine particles contained in each droplet being discharged.

It is an object of the invention to provide an inkjet head that permits ink to be easily circulated therein and that is applicable to ink containing fine particles, without making a structure thereof complicated, and to provide a method for manufacturing the same.

### Solution to Problem

In order to resolve the above problems, an inkjet head of the invention comprises:

a manifold,

a piezoelectric substrate that is mounted in the manifold and that has a plurality of ink grooves separated from one another by partition walls and provided with electrodes on inner walls thereof, and

a nozzle plate that is mounted on top of the partition walls of the piezoelectric substrate and that covers upper side of the plurality of ink grooves so as to define the plurality of ink grooves as a plurality of separated ink chambers, wherein

the plurality of ink grooves are formed in parallel with one another so as to penetrate the piezoelectric substrate from one end to the other end thereof,

the manifold has a first common ink groove communicating with the plurality of separated ink chambers on one end side of the separated ink chambers and having a second common ink groove communicating with the plurality of separated ink chambers on the other end side of the separated ink chambers.

According to the inkjet head of the invention, the manifold has the first common ink groove communicating with the plurality of separated ink chambers on the one end side of the separated ink chambers and has the second common ink groove communicating with the plurality of separated ink chambers on the other end side of the separated ink chambers, and thus appropriate adjustment in widths, depths and the like of the first common ink groove and the second common ink groove can sufficiently decrease flow passage resistances of the first common ink groove and the second common ink groove in comparison with flow passage resistances of the separated ink chambers so that ink flow via the separated ink chambers in the inkjet head can easily be promoted. This has no influence on number (what is called “yield per wafer”) of the inkjet heads that can be obtained from one wafer-like piezoelectric substrate.

Therefore, the inkjet head can be provided that permits ink to be easily circulated therein and that is applicable to ink containing fine particles, without making the structure thereof complicated.

In an embodiment, the ink grooves are linearly formed with a fixed depth, and wherein bottom surfaces of the ink grooves are formed so as to parallel a bottom surface of the piezoelectric substrate.

According to the inkjet head of the embodiment, the ink grooves that are linearly formed with the fixed depth and the bottom surfaces of the ink grooves that are formed so as to parallel the bottom surface of the piezoelectric substrate are advantageous in that the machining of the ink grooves only requires movement of a rotating dicing blade in a straight line without requiring the machining method with use of vertical movement of the dicing blade, i.e., so-called chopper machining, and a special dicing machine.

In an embodiment, the nozzle plate is mounted so as to spread across the piezoelectric substrate and the manifold, covers upper side of the first common ink groove so as to define the first common ink groove as a first common ink chamber, and covers upper side of the second common ink groove so as to define the second common ink groove as a second common ink chamber.

According to the inkjet head of the embodiment, the nozzle plate covers the upper side of the first common ink groove so as to define the first common ink groove as the first common ink chamber and covers the upper side of the second common ink groove so as to define the second common ink groove as the second common ink chamber, so that the plurality of ink grooves, the first common ink groove, and the second common ink groove can simultaneously be covered by the nozzle plate so as to simultaneously define the plurality of separated ink chambers, the first common ink chamber, and the second common ink chamber, and so that efficiency of assembling works can be improved.

In an embodiment, separated ink chambers having nozzle holes formed thereon among the plurality of separated ink chambers are discharge ink chambers, and wherein

the discharge ink chambers are formed only of regions contributing to discharge.

According to the inkjet head of the embodiment, the discharge ink chambers are formed only of the regions contributing to the discharge, so that the nozzle holes can be formed corresponding to some desired ink grooves in response to the demands for decrease in nozzle hole density that have been caused by increase in size of liquid crystal screens.

In an embodiment, separated ink chambers having no nozzle holes formed thereon among the plurality of separated ink chambers are dummy ink chambers.

According to the inkjet head of the embodiment, the separated ink chambers having no nozzle holes formed thereon, among the plurality of separated ink chambers, are the dummy ink chambers, so that passage of ink through the dummy ink chambers can reduce the flow passage resistance of the plurality of separated ink chambers as a whole and can smooth the circulation of the ink even if sufficient sectional areas of the flow passages cannot be ensured and the flow passage resistance cannot be reduced only by the provision of the discharge ink chambers. As a result, the precipitation of the fine particles can be prevented and a number of the fine particles contained in each droplet being discharged can be stabilized.

An embodiment comprises a first ink distribution mechanism for expelling all portions of ink supplied into the first common ink chamber, except a portion thereof that is to be consumed in discharge from the separated common ink chambers, via the separated common ink chambers into the second common ink chamber.

Herein the first ink distribution mechanism is a driving source for producing ink flow, such as a structure that provides a head difference and a device that controls a pressure in an ink tank.

According to the inkjet head of the embodiment, the first ink distribution mechanism expels all the portions of the ink supplied into the first common ink chamber, except the portion thereof to be consumed in the discharge from the separated common ink chambers, via the separated common ink chambers into the second common ink chamber and is thus capable of positively producing ink flow passing through the separated ink chambers.

An embodiment comprises a second ink distribution mechanism for expelling all portions of ink supplied into the second common ink chamber, except a portion thereof that is to be consumed in discharge from the separated common ink chambers, via the separated common ink chambers into the first common ink chamber.

Herein the second ink distribution mechanism is a driving source for producing ink flow, such as a structure that provides a head difference and a device that controls a pressure in an ink tank.

According to the inkjet head of the embodiment, the second ink distribution mechanism discharges all the portions of ink supplied into the second common ink chamber, except the portion thereof to be consumed in the discharge from the separated common ink chambers, via the separated common ink chambers into the first common ink chamber and is thus capable of positively producing ink flow passing through the separated ink chambers.

In an embodiment, the electrodes formed on the inner walls of the ink grooves extend to side face parts of the piezoelectric substrate on which the separated ink chambers open.

According to the inkjet head of the embodiment, the electrodes extend to the side face part of the piezoelectric substrate and thus can be formed by sputtering.

In an embodiment, the electrodes extend to the only one side face part of the piezoelectric substrate.

According to the inkjet head of the embodiment, the electrodes extending to the only one side face part of the piezoelectric substrate have only to be formed on the one side face of the piezoelectric substrate and can be formed thereon by the electrode film formation on the connected substrate corresponding to two inkjet heads and later split thereof at the center part. This halves quantity of work in comparison with the electrode film formation on the separated piezoelectric substrates and improves work efficiency.

In an embodiment, the electrodes are connected to an external connection substrate on the side face part of the piezoelectric substrate.

According to the inkjet head of the embodiment, the electrodes connected to the external connection substrate on the side face part of the piezoelectric substrate make it possible to thereby apply a voltage based on image data to the partition walls on both sides of each ink groove on the piezoelectric substrate and to drive ink channels from outside.

An inkjet head manufacturing method of the invention comprises steps of:

forming a plurality of ink grooves in parallel with one another by groove machining on a piezoelectric substrate so that the grooves penetrate the piezoelectric substrate from one end to the other end thereof,

forming a conductor film as the electrodes on the piezoelectric substrate,

mounting the piezoelectric substrate on a manifold so as to form in the manifold a first common ink groove communicating with one end side of the plurality of ink grooves and a second common ink groove communicating with the other end side of the plurality of ink grooves, and
mounting a nozzle plate on the piezoelectric substrate and the manifold so as to cover the plurality of ink grooves, the first common ink groove, and the second common ink groove, thereby defining the ink grooves as separated ink chambers, the first common ink groove as a first common ink chamber, and the second common ink groove as a second common ink chamber.

According to the inkjet head manufacturing method of the invention, which includes steps of forming the ink grooves on the piezoelectric substrate, forming the electrodes on the piezoelectric substrate, mounting the piezoelectric substrate on the manifold so as to form in the manifold the first common ink groove and the second common ink groove, and mounting the nozzle plate on the piezoelectric substrate and the manifold so as to define the ink grooves as the separated ink chambers, the first common ink groove as the first common ink chamber, and the second common ink groove as the second common ink chamber, appropriate adjustment in the widths, depths and the like of the first common ink groove and the second common ink groove can sufficiently decrease the flow passage resistances of the first common ink groove and the second common ink groove in comparison with the flow passage resistance of the separated ink chambers so that the ink flow via the separated ink chambers in the inkjet head can easily be promoted. This has no influence on the number (what is called “yield per wafer”) of the inkjet heads that can be obtained from one wafer-like piezoelectric substrate.

Therefore, the inkjet head can be provided that permits ink to be easily circulated therein and that is applicable to ink containing fine particles, without making the structure thereof complicated.

In an embodiment, the ink grooves are linearly formed with a fixed depth, and wherein bottom surfaces of the ink grooves are formed so as to parallel a bottom surface of the piezoelectric substrate.

According to the inkjet head manufacturing method of the embodiment, the ink grooves that are linearly formed with the fixed depth and the bottom surfaces of the ink grooves that are formed so as to parallel the bottom surface of the piezoelectric substrate are advantageous in that the machining of the ink grooves only requires movement of a rotating dicing blade in a straight line without requiring the machining method with use of vertical movement of the dicing blade, i.e., so-called chopper machining, and a special dicing machine.

### Advantageous Effects of Invention

According to the inkjet head of the invention, the manifold has the first common ink groove communicating with the plurality of separated ink chambers on the one end side of the separated ink chambers and has the second common ink groove communicating with the plurality of separated ink chambers on the other end side of the separated ink chambers so that the inkjet head can be provided that permits ink to be easily circulated therein and that is applicable to ink containing fine particles, without making the structure thereof complicated.

According to the inkjet head manufacturing method of the invention, which includes steps of forming the ink grooves on the piezoelectric substrate, forming the electrodes on the piezoelectric substrate, mounting the piezoelectric substrate on the manifold so as to form in the manifold the first common ink groove and the second common ink groove, and mounting the nozzle plate on the piezoelectric substrate and the manifold so as to define the ink grooves as the separated ink chambers, the first common ink groove as the first common ink chamber, and the second common ink groove as the second common ink chamber, the inkjet head can be provided that permits ink to be easily circulated therein and that is applicable to ink containing fine particles, without making the structure thereof complicated.

### BRIEF DESCRIPTION OF DRAWINGS

FIG. 1 is a perspective view showing an embodiment of an inkjet head of the invention;

FIG. 2 is a perspective view showing the inkjet head from which a nozzle plate has been detached;

FIG. 3 is a sectional view taken along a line III-III in FIG. 1;

FIG. 4 is a perspective view of a piezoelectric substrate and an interconnection substrate;

FIG. 5 is an exploded view of a manifold;

FIG. 6 is a sectional view taken along a line VI-VI in FIG. 5;

FIG. 7 is a sectional view taken along a line VII-VII in FIG. 5;

FIG. 8 is a perspective view of a portion of the inkjet head;

FIG. 9 is an illustration of a first step of an inkjet head manufacturing method of the invention;

FIG. 10 is an illustration of a second step of an inkjet head manufacturing method of the invention;

FIG. 11 is an illustration of a third step of an inkjet head manufacturing method of the invention;

FIG. 12 is an illustration of a fourth step of an inkjet head manufacturing method of the invention;

FIG. 13 is an enlarged fragmentary view of FIG. 12;

FIG. 14 is an illustration of a fifth step of an inkjet head manufacturing method of the invention;

FIG. 15 is an exploded view of a conventional inkjet head; and

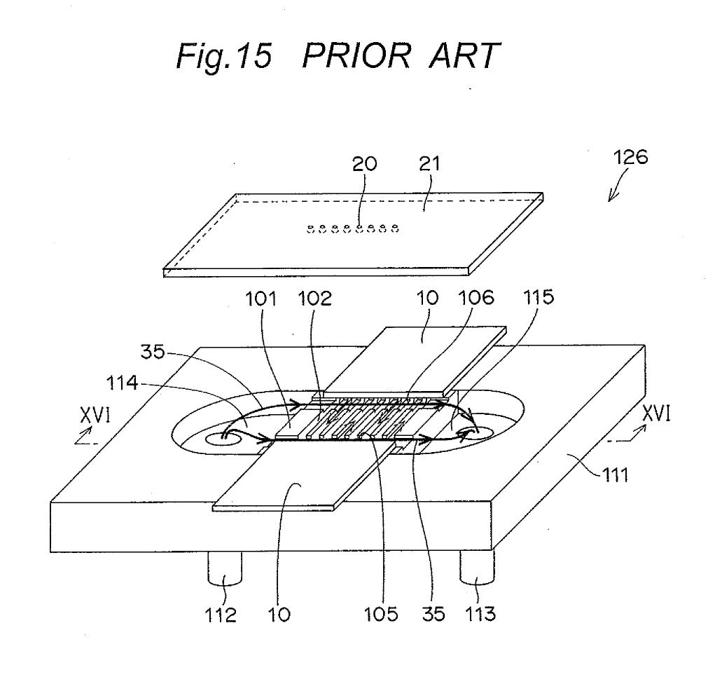

FIG. 16 is a sectional view taken along a line XVI-XVI in FIG. 15;

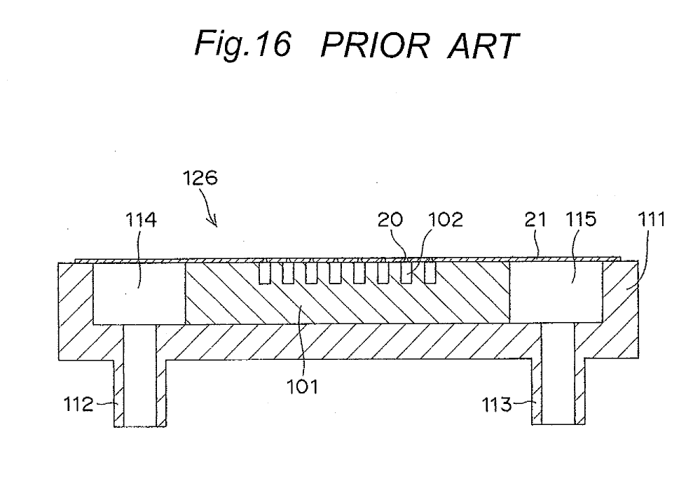

### DESCRIPTION OF EMBODIMENTS

Hereinbelow, the invention will be described in detail with reference to an embodiment shown in the drawings.

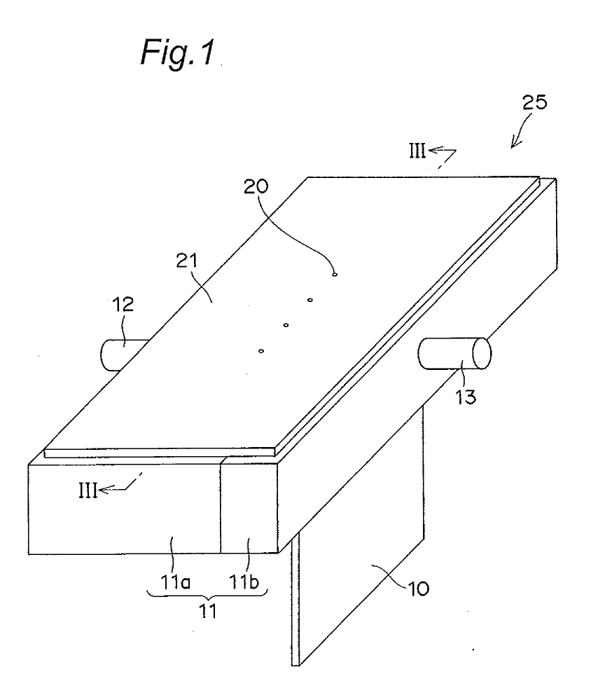

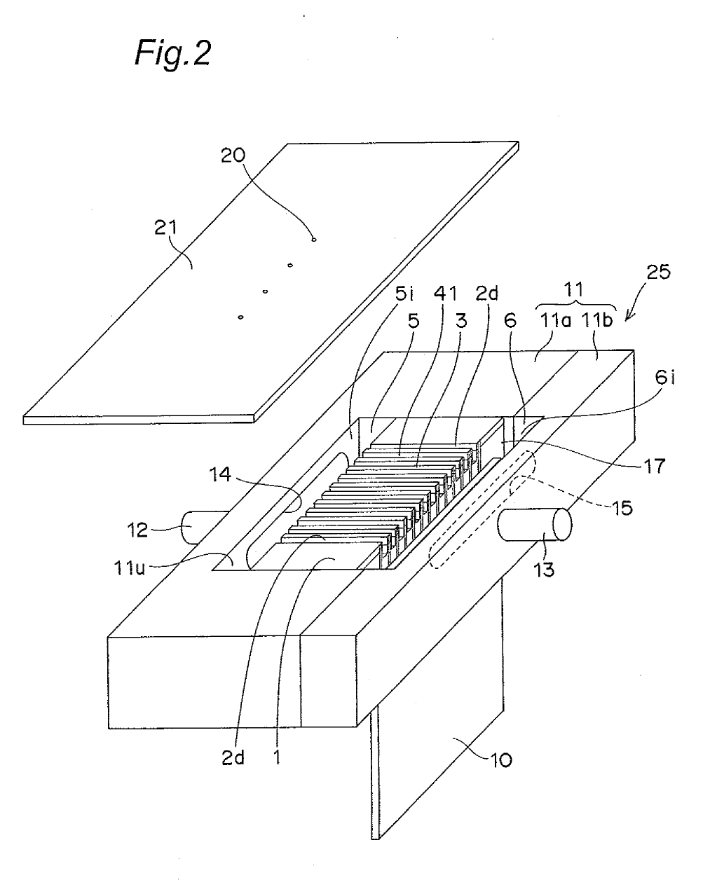

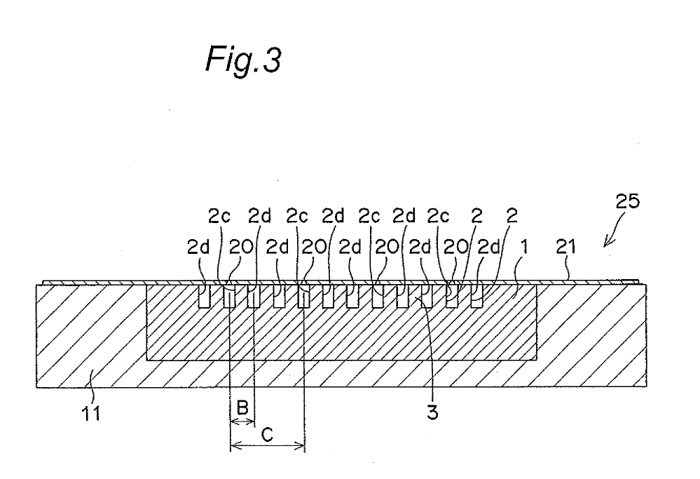

The embodiment of inkjet head of the invention will be described with reference to FIGS. 1 through 8. FIG. 1 shows an inkjet head 25 of the embodiment. FIG. 2 shows the inkjet head 25 from which a nozzle plate 21 has been detached. FIG. 3 shows a sectional view taken along a line in FIG. 1.

As shown in FIG. 2, the inkjet head 25 has a piezoelectric substrate 1, a nozzle plate 21, and a manifold 11. The piezoelectric substrate 1 has a plurality of ink grooves 41, on a top surface thereof, which are separated from one another by partition walls 3 and which are provided with electrodes on inner walls of the grooves.

The plurality of ink grooves 41 are formed in parallel with one another along a direction of a short side of the piezoelectric substrate 1 so as to penetrate from one end to the other end of the piezoelectric substrate 1. The ink grooves 41 are linearly formed with a fixed depth, and bottom surfaces of the ink grooves 41 are formed so as to parallel a bottom surface of the piezoelectric substrate.

As shown in FIG. 2, the piezoelectric substrate 1 is mounted on the manifold 11 so as to define a first common ink groove 5 communicating with a plurality of separated ink chambers 2 on one end side of the separated ink chambers 2 and so as to define a second common ink groove 6 communicating with the plurality of separated ink chambers 2 on the other end side of the separated ink chambers 2. In other words, the piezoelectric substrate 1 is accommodated in a recess 11u on a top surface of the manifold 11 so as to form the first common ink groove 5 and the second common ink groove 6.

As shown in FIG. 3, the nozzle plate 21 is bonded onto top of the partition walls 3 of the piezoelectric substrate 1 so as to cover upper side of the plurality of ink grooves 41 and define the plurality of ink grooves 41 as the plurality of separated ink chambers 2, and is simultaneously bonded onto the top surface of the manifold 11 so as to cover top faces of the first common ink groove 5 and the second common ink groove 6 and define the grooves as a first common ink chamber 5i and a second common ink chamber 6i.

The nozzle plate 21 on which nozzle holes 20 are formed corresponding to all the ink grooves 41 can be bonded thereto or the nozzle holes 20 can be formed corresponding to some of the ink grooves 41 in response to demands for decrease in nozzle density that have been caused by increase in size of liquid crystal screens. The separated ink chambers 2 corresponding to the ink grooves 41 having the nozzle holes 20 formed thereon serve as discharge ink chambers 2c. On the other hand, the separated ink chambers 2 corresponding to the ink grooves 41 having no nozzle holes 20 formed thereon form dummy ink chambers 2d that do not contribute to the discharge of ink but contribute to ink circulation and to decrease in flow passage resistance by flow of the ink into the dummy ink chambers 2d.

That is, the nozzle plate 21 has the nozzle holes 20 in positions corresponding to the discharge ink chambers 2c and has no nozzle holes 20 in positions corresponding to the dummy ink chambers 2d. In the embodiment, as shown in FIG. 3, the separated ink chambers 2 are arranged with a pitch B and the nozzle holes 20 are arranged with a pitch C. The dummy ink chambers 2d are placed at least on both ends in a row of the separated ink chambers 2 corresponding to the nozzle holes 20.

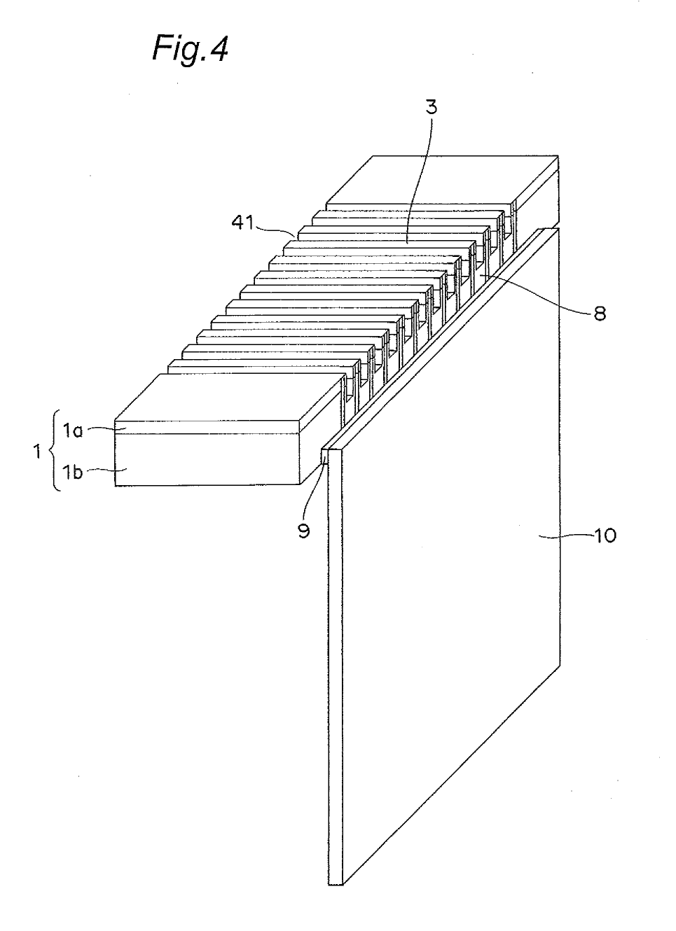

In FIG. 4 are shown the piezoelectric substrate 1 and an interconnection substrate 10 that have been taken out from a lower structure shown in FIG. 2. The piezoelectric substrate 1 is formed by bonding an upper board 1a and a lower board 1b. On one side face part (end face part) of the piezoelectric substrate 1 are formed electrode drawing parts 8 each being a portion of each electrode. The interconnection substrate 10 is connected to the electrode drawing parts 8 through an anisotropic conductive film 9 (which will be referred to as “ACF”, hereinbelow).

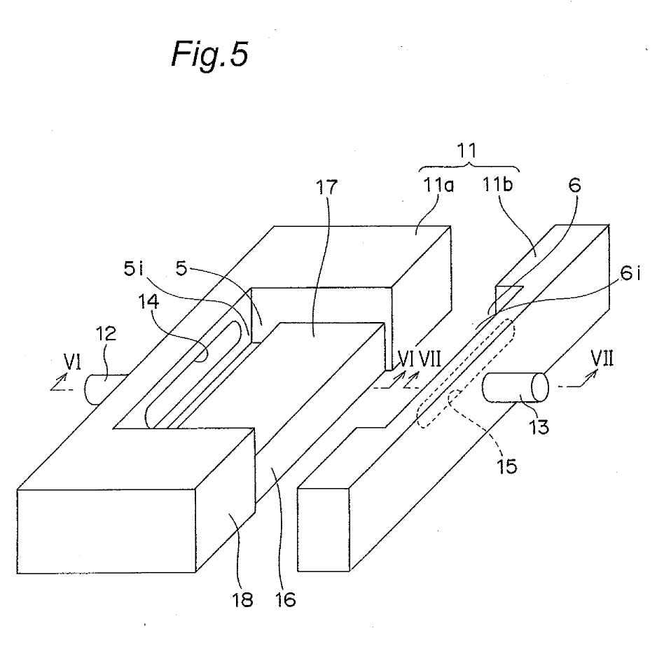

In FIG. 5 is shown the manifold 11 that is left as a result of removal of the piezoelectric substrate 1 and the interconnection substrate 10 from the lower structure shown in FIG. 2 and that has been disassembled. The manifold 11 is formed by bonding a first part 11a and a second part 11b. The first part 11a has a recess 17 for piezoelectric substrate. At center of a boding surface 18 of the first part 11a is provided a recess 16 for interconnection substrate.

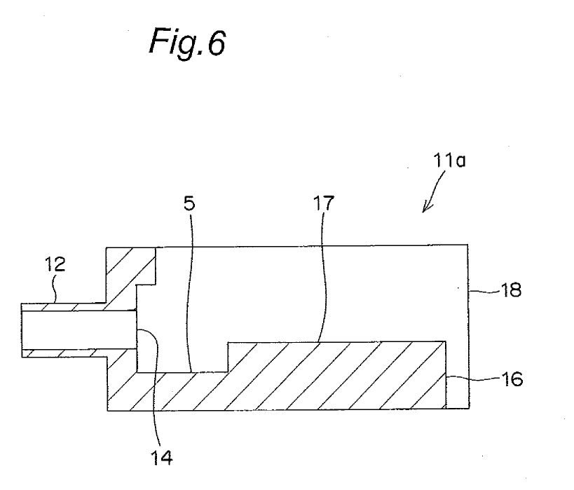

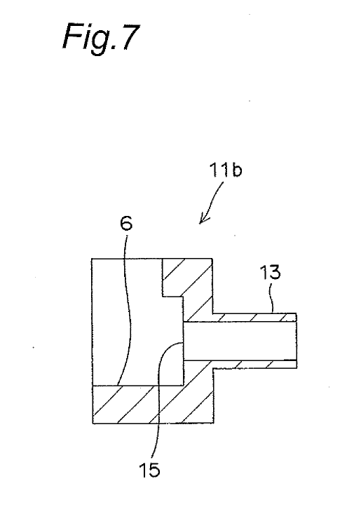

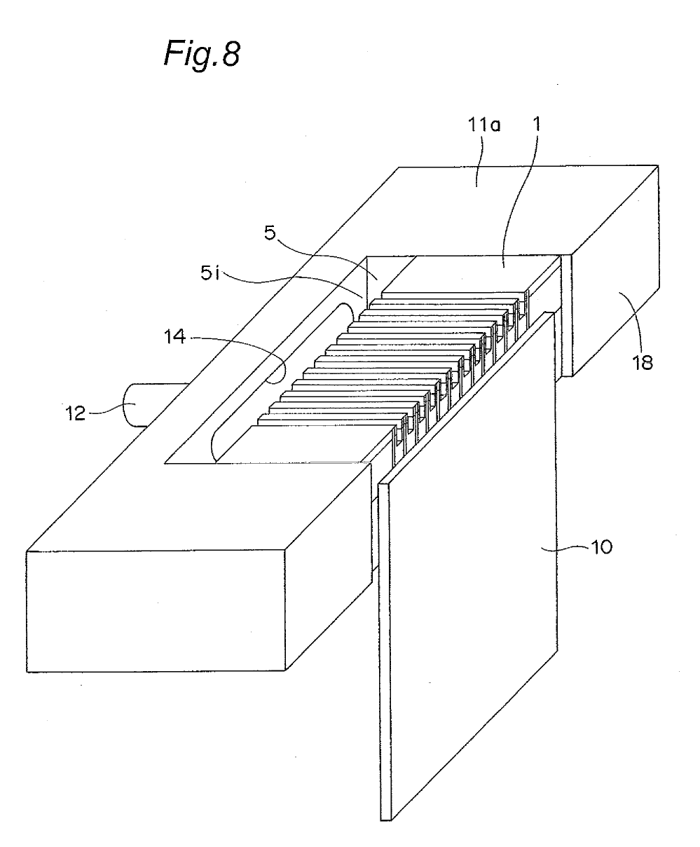

In FIG. 6 is shown a sectional view taken along a line VI-VI in FIG. 5. In FIG. 7 is shown a sectional view taken along a line VII-VII in FIG. 5. The first part 11a has a recess that is to form the first common ink groove 5 and has a nipple opening 14 that is on an inner wall of the first common ink groove 5 and that communicates with an ink supply pipe 12. The second part 11b has a recess that is to form the second common ink groove 6 and has a nipple opening 15 that is on an inner wall of the second common ink groove 6 and that communicates with an ink supply pipe 13. The first part 11a and the structure shown in FIG. 4 are assembled as shown in FIG. 8. That is, the piezoelectric substrate 1 is accommodated in the recess 17 for piezoelectric substrate and the interconnection substrate 10 is accommodated in the recess 16 for interconnection substrate.

Hereinbelow, flow of ink will be described with reference to FIGS. 2 and 3. The ink supplied from a first ink tank not shown to the inkjet head 25 flows through the ink supply pipe 12 and the nipple opening 14 into the first common ink chamber 5i. The ink having arrived at the first common ink chamber 5i subsequently passes through any of the plurality of separated ink chambers 2 formed in the piezoelectric substrate 1 and flows into the second common ink chamber 6i. When the ink passes through the separated ink chambers 2, all of the discharge ink chambers 2c and of the dummy ink chambers 2d are used as ink flow passages. The ink having arrived at the second common ink chamber 6i passes through the nipple opening 15 and the ink supply pipe 13, and is discharged into a second ink tank not shown.

In the configuration of the inkjet head 25 in the embodiment, the ink is thus separated and flows through the plurality of separated ink chambers 2 when moving from the first common ink chamber 5i to the second common ink chamber 6i. A portion of the ink that has passed the discharge ink chambers 2c of the separated ink chambers 2 is consumed by being discharged from the nozzle holes 20, while the ink that has passed the discharge ink chambers 2c and that has not been discharged from the nozzle holes 20 and the ink that has passed the dummy ink chambers 2d all flow smoothly into the second common ink groove 6.

Accordingly, the ink can smoothly be circulated and the ink flow passing also inside of the ink chambers 2 that are spaces in immediate vicinity of the nozzle holes 20 can positively be formed. This suppresses precipitation or flotage of fine particles that may be contained in the ink and makes it possible to stabilize number of the fine particles contained in each droplet being discharged.

A direction of the flow of ink is not limited to that described above but may be opposite to that. In the flow in the opposite direction, ink supplied from the ink supply pipe 13 into the inkjet head 25 flows through the nipple opening 15 into the second common ink chamber 6i. The ink subsequently passes through any of the plurality of separated ink chambers 2 formed in the piezoelectric substrate 1 and flows into the first common ink chamber 5i. The ink passes through the nipple opening 14 and is discharged into the ink supply pipe 12. Such a path may be used.

Conceivable methods of producing the flow in the ink are a method using a head difference, a method using control over pressures in the ink tanks, and the like.

As a first ink distribution mechanism for making ink flow from the first common ink chamber 5i to the second common ink chamber 6i and a second ink distribution mechanism for making ink flow from the second common ink chamber 6i to the first common ink chamber 5i, there is used a structure that provides a head difference, a device that controls pressures in the ink tanks, or the like, for instance.

When ink is made to flow from the first ink tank not shown via the inkjet head 25 to the second ink tank not shown, specifically, the direction of the supply of the ink is preferably reversed the moment an amount of the ink discharged into and accumulated in the second ink tank reaches a given value. Then the ink supplied from the second ink tank not shown passes through the inkjet head 25 and is discharged into the first ink tank not shown.

Such shuttling of ink between the two ink tanks makes it possible to endlessly circulate the ink. This ensures that the ink flow in either of the directions always exists in the inkjet head 25. Thus the ink flow in either of the directions passes through the ink chambers 2 in the inkjet head 25, so that ink flow passing through the spaces in immediate vicinity of the nozzle holes 20 can positively be formed.

Though the inkjet heads of the prior art that are supplied with ink containing fine particles such as beads entail a fear that a difference in specific gravity between solvent of the ink and the contained fine particles may cause precipitation and flotage of the fine particles and uneven distribution of concentrations of the fine particles in the ink and consequently entail fears of a variation in number of the fine particles contained in each droplet being discharged, deterioration in performance of the products, and occurrence of defective products, the configuration of the invention in which the ink flow passing through the ink chambers in immediate vicinity of the nozzle holes can positively be formed suppresses the precipitation or flotage of the fine particles and ensures the discharge with stabilization in the number of the fine particles contained in each droplet being discharged.

Even if sufficient sectional areas of the flow passages cannot be ensured and the flow passage resistance cannot be reduced only by the provision of the plurality of discharge ink chambers 2c, the inkjet head 25 of the embodiment that is provided with the dummy ink chambers 2d having no nozzle holes 20 formed thereon in addition to the discharge ink chambers 2c having the nozzle holes 20 formed thereon can reduce the flow passage resistance of the plurality of separated ink chambers 2 as a whole and can smooth the circulation of the ink. As a result, the precipitation of the fine particles can be prevented and the number of the fine particles contained in each droplet being discharged can be stabilized.

From this viewpoint, there are preferably formed a plurality of the dummy ink chambers 2d. The dummy ink chambers 2d serve to decrease the flow passage resistance and do not contribute to the discharge. The nozzle holes 20 are not formed in the positions on the nozzle plate 21 corresponding to the dummy ink chambers 2d making no contribution to the discharge, so that such troubles as clogging of the nozzle holes 20 can be avoided and so that unnecessary ink consumption can be suppressed.

The smaller a sectional area of a flow passage and the larger a length of the flow passage, the larger a resistance of the flow passage, meaning that flow passage resistance can be equalized in each of the discharge ink chambers 2c and in each of the dummy ink chambers 2d by equalization of the sectional area and length in each of the dummy ink chambers 2d and in each of the discharge ink chambers 2c. The equalization of the flow passage resistance results in equalization between a quantity of ink passing through each of the discharge ink chambers 2c and a quantity of ink passing through each of the dummy ink chambers 2d and no difference in flow velocity therebetween and thus prevents ink congestion. The prevention of the ink congestion suppresses change in composition of the ink, the precipitation or flotage of the fine particles, and the like and ensures the discharge with further stabilization of the number of the fine particles contained in each droplet being discharged.

The larger a thickness of the partition walls 3, the higher a “drive voltage” required for deforming the partition walls 3 that separate the separated ink chambers 2 of the inkjet head 25 based on the invention. Increase in the pitch of the arrangement of the separated ink chambers 2 that entails decrease in density of the separated ink chambers 2 results in increase in the thickness of the partition walls 3. Recently, the demands for decrease in density of nozzle holes, resulting from increase in size of liquid crystal screens, cause a trend for the thickness of the partition walls 3 to increase, arousing apprehensions about increase in the drive voltage.

The increase in the drive voltage causes increase in quantity of heat generated by the piezoelectric substrate 1, in proportion to a magnitude of the drive voltage. The heat generation from the piezoelectric substrate 1 causes change in viscosity of ink. This makes it difficult to ensure the discharge with stabilization of the number of fine particles contained in each droplet being discharged. In order to avoid such situation, it is necessary to lower the quantity of the generated heat. For lowering the quantity of the generated heat, it is desirable for the drive voltage for the inkjet head 25 to be as low as possible.

In order to suppress the increase in the drive voltage on condition of low density of the arrangement pitch of the separated ink chambers 2, the separated ink chambers 2 are preferably arranged with a normal arrangement pitch with the thickness of the partition walls 3 set to such an extent that the discharge can be performed with a normal drive voltage. Under this condition, preferably, only the separated ink chambers 2 corresponding to the arrangement pitch with a desired low density are made into the discharge ink chambers 2c and are provided with the nozzle holes 20, and other separated ink chambers are made into the dummy ink chambers 2d and are not provided with the nozzle holes 20. Thus the nozzle plate 21 on which the nozzle holes 20 are sparsely placed are preferably bonded. The configuration shown in FIG. 3 is an example to which this idea is applied.

Hereinbelow, a specific example will be described in conjunction with specific numerical values. In the configuration shown in FIG. 3, for instance, in which the separated ink chambers 2 are arranged so that the arrangement pitch B of the separated ink chambers 2 is 169 μm (corresponding to 150 DPI), it is assumed that the drive voltage for the inkjet head 25 is 15 V. When the discharge ink chambers 2c arranged with an arrangement pitch of 500 μm are demanded without change in the drive voltage, preferably, grooves that are to be made into the separated ink chambers 2 are initially formed with a pitch of 169 μm (corresponding to 150 DPI) on the piezoelectric substrate 1 and the nozzle plate 21 having the nozzle holes 20 formed thereon with the arrangement pitch C of about 507 μm (corresponding to 50 DPI) is bonded on the plurality of grooves. That is, the inkjet head 25 is preferably constructed by the bonding of the nozzle plate 21 on which one nozzle hole 20 is provided for three separated ink chambers 2 as shown in FIG. 3.

Among the separated ink chambers 2, those on which the nozzle holes 20 are not opened are used as the dummy ink chambers 2d. The dummy ink chambers 2d are used for circulating ink. Even if the flow passage resistance cannot sufficiently be reduced only by the plurality of discharge ink chambers 2c, such provision of the plurality of dummy ink chambers 2d reduces the flow passage resistance and consequently prevents the precipitation of the fine particles, thereby ensuring the discharge with stabilization of the number of the fine particles contained in each droplet being discharged.

In this arrangement in which the arrangement pitch C of the nozzle holes 20 is about 507 μm, use of the inkjet head 25 with a 9.53° turn thereof in a plane of the nozzle plate 21 results in an apparent nozzle arrangement pitch of 500 μm in the device as a whole.

Such a configuration decreases only the density of the arrangement pitch of the actual nozzle holes 20 without change in pitch of machining of the grooves on the piezoelectric substrate. The separated ink chambers 2 having no nozzle holes 20 formed thereon are used as the dummy ink chambers 2d, and thus the dummy ink chambers 2d outnumbering the discharge ink chambers 2c can be formed as necessary.

Subsequently, a method for manufacturing the inkjet head of the invention will be described with reference to FIGS. 9 through 14, FIGS. 1, 4, 5, and 8.

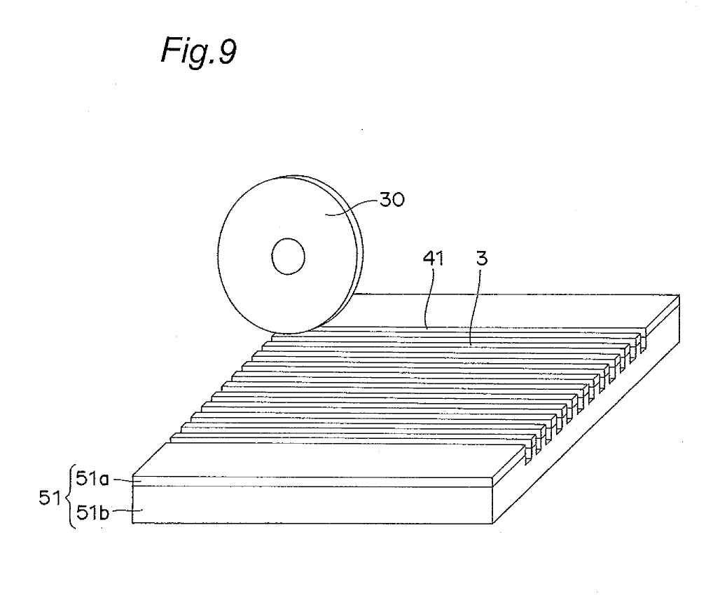

Initially, the piezoelectric substrate 1 is produced. For the production, two wafer-like piezoelectric substrates 51a, 51b different in direction of polarization are bonded to each other, as shown in FIG. 9. Thus a wafer-like piezoelectric substrate 51 is obtained.

Subsequently will be described a process of forming the plurality of ink grooves, which are formed by machining of the grooves on the piezoelectric substrate 51. As shown in FIG. 9, the process can be carried out by machining of the grooves with repetitive running of a dicing blade 30 for use in a common dicing machine. The one piezoelectric substrate 51 is split later into a large number of piezoelectric substrates 1. As shown in FIG. 9, the plurality of ink grooves 41 formed by the machining of the grooves are arranged with a given depth in parallel to one another and are separated from one another by the plurality of elongate partition walls 3 arranged in parallel to one another. The ink grooves 41 have only to be elongate grooves having specified widths and depths, and the machining of each groove is performed so as to form a straight line.

Practically, the dicing blade 30 having a width of 80 μm is used on the wafer-like piezoelectric substrate 51 having a thickness of 3 mm, so as to work 134 lengths of the ink grooves 41 having a depth of 260 μm on a section that is to be one piezoelectric substrate 1. The ink grooves 41 are later made into the separated ink chambers 2.

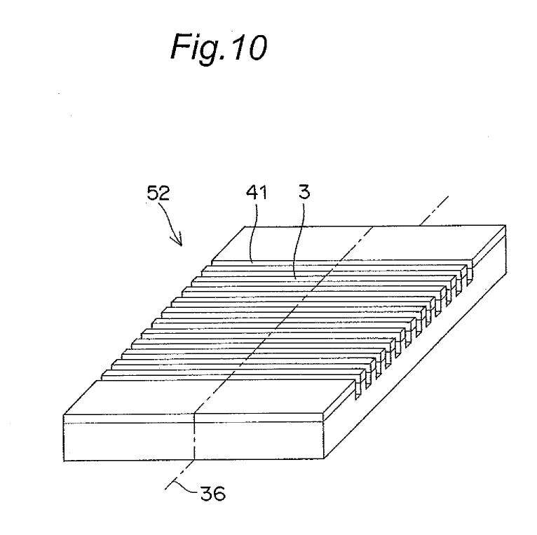

Subsequently, a process of forming the electrodes will be described in which the wafer-like piezoelectric substrate 51 having undergone the machining of the grooves is split by the dicing blade 30 so as to form piezoelectric substrates 52 having a size as large as two piezoelectric substrates 1 connected to each other, as shown in FIG. 10. After that, a process is carried out for forming a conductor film on the inner walls of the plurality of ink grooves 41 and thereby producing an electrode.

The formed electrode is for driving the partition walls 3 in the share mode after the inkjet head 25 is finished. The electrode is a copper film, which is formed by sputtering with use of an RF (Radio Frequency) magnetron sputtering apparatus. By the formation of the film, the electrode is formed so as to cover not only both side surfaces of the partition walls 3 but also top surfaces of the partition walls 3, side surfaces and a top surface of the piezoelectric substrate 52.

Though the formation of the electrodes on side surfaces of the piezoelectric substrates 1 requires the film formation with exposure of the side surfaces of the piezoelectric substrates that are desired to be provided with the electrodes and therefore requires the electrode film formation on the piezoelectric substrates 1 that have been cut from the wafer-like piezoelectric substrate and that correspond to respective inkjet heads 25, work efficiency is poor in the film formation on a large number of the separated piezoelectric substrates 1.

The electrode drawing parts 8 have only to be formed on one side surface of the piezoelectric substrate 1, and thus the piezoelectric substrates 1 each having the electrode on the one side surface thereof can be produced by the electrode film formation on the substrate corresponding to two connected inkjet heads 25 and later split thereof at center part.

This halves quantity of work in comparison with the electrode film formation on the separated piezoelectric substrates 1 and improves work efficiency.

Subsequently, the top surface of the piezoelectric substrate 52 is ground by the dicing blade 30 so as to achieve a quantity of removal of 10 μm, so that the unnecessary electrode having covered the top surface of the piezoelectric substrate 52 is removed. Then the electrode having covered the top surfaces of the partition walls 3 is simultaneously removed, and thus the electrode is separated so as to correspond to the ink grooves 41 in a view from above.

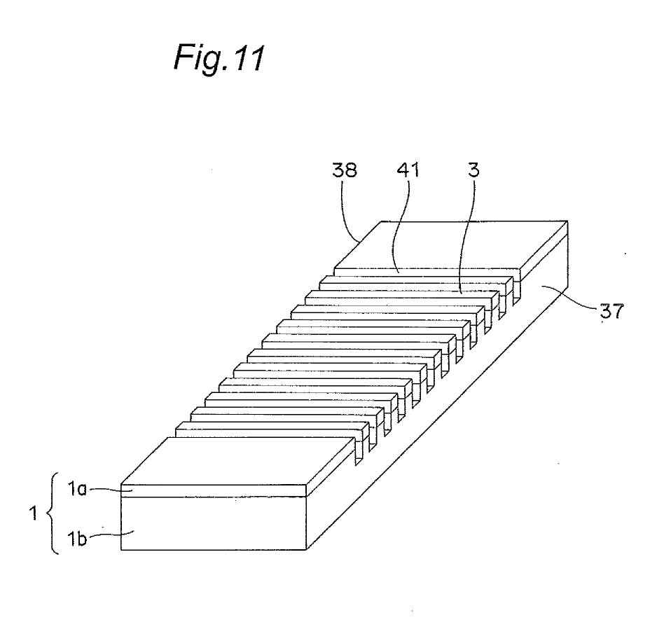

Subsequently, the piezoelectric substrate 52 is cut into halves, having a size corresponding to one inkjet head as shown in FIG. 11, by the dicing blade 30 in a position shown by a dotted line 36 as described above. Thus the piezoelectric substrates 1 are obtained. Out of both end faces of the piezoelectric substrate 1, as a result of the cutting, no electrode exists on a new end face produced by the cutting, while the electrode exists on the opposite end face. In FIG. 11, the electrode exists on an end face 37, while no electrode exists on an end face 38. At this point of time, there is continuity between the electrodes in the ink grooves 41 through the electrode covering the end face 37.

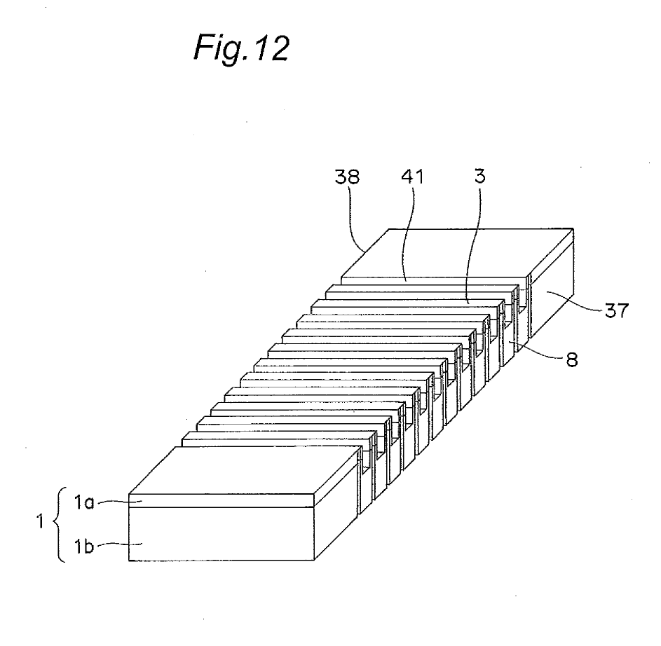

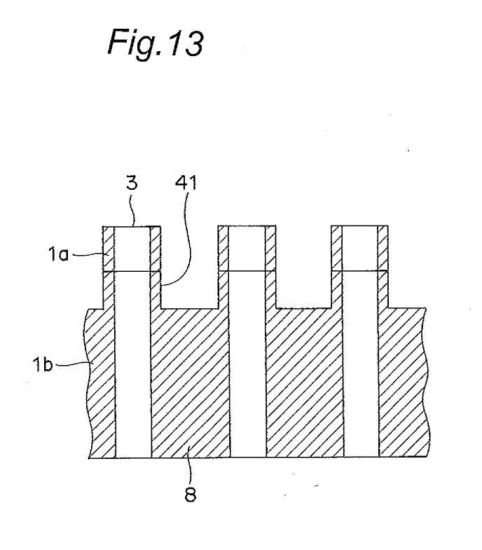

Subsequently, the piezoelectric substrate 1 is fixed so that the end face 37 is directed upward, and portions of the electrode on the end face 37 that correspond to center lines of the partition walls 3 are linearly ground and removed by the dicing blade 30. A result of that is as shown in FIG. 12. In FIG. 13 is shown an enlarged fragmentary view of the end face 37 in FIG. 12. Hatched sections in FIG. 13 are covered with the electrodes. At this point of time, the electrodes in the ink grooves 41 are electrically isolated from one another completely and individually. On portions of the end face corresponding to the ink grooves 41, the electrodes remain without being ground and removed. The remaining electrodes form the electrode drawing parts 8. Instead of such a method of removal, a process of removing the electrode can be carried out by linear scanning with laser of the portions of the end face 37 that correspond to the center lines of the partition walls 3. As methods other than those, there can be enumerated a method of carrying out etching with photo lithography and the like.

As shown in FIG. 4, subsequently, the interconnection substrate 10 as an external substrate is connected to the electrode drawing parts 8 through the ACF 9. This makes it possible to apply a voltage based on image data to the partition walls 3 on both sides of each ink groove 41 on the piezoelectric substrate 1 and to drive the ink channels from outside. Among methods of the connection to the external substrate are a method of directly connecting leads of the external substrate to the external connection terminals of the piezoelectric substrate 1, a method of wire bonding of the leads of the external substrate to the external connection terminals of the piezoelectric substrate 1, and the like, besides the connecting method using the ACF 9.

After that, electrode protection films (not shown) with a thickness of about 10 μm are formed in order to protect the electrodes formed on the inner wall surfaces of the ink grooves 41 of the piezoelectric substrate 1. The electrode protection films adhere onto every exposed surfaces of the piezoelectric substrate 1 and the interconnection substrate 10 in a process of formation thereof, and thus the interconnection substrate 10 not requiring the adhesion is masked in advance with masking tapes or the like so as to prevent the adhesion of the electrode protection films.

Subsequently, a process of mounting the piezoelectric substrate on the manifold will be described in which the piezoelectric substrate 1 is mounted on the manifold 11 having a recess for common ink chambers that is to form the first common ink chamber 5i and the second common ink chamber 6i. For the process, the manifold 11 as shown in FIG. 5 has been manufactured in advance. The manifold 11 has a two-piece structure composed of the first part 11a and the second part 11b.

The first part 11a of the manifold 11 is formed of a plate member having a thickness of 10 mm and made of aluminum, stainless steel, ceramic or the like. A top surface of the first part 11a is subjected to recess machining with a depth of 3 mm as large as a thickness of the piezoelectric substrate 1 and with a width and a length as large as those of the piezoelectric substrate 1 so that the recess 17 for piezoelectric substrate is formed as shown in FIG. 5. The first common ink groove 5 is formed so as to communicate with the recess 17 for piezoelectric substrate. For the first common ink groove 5, recess machining is performed with a depth of 4 mm, and a width and a length for the recess machining are as large as those of the piezoelectric substrate 1.

For the boding surface 18 of the first part 11a, recess machining is performed sideward with a depth of 0.25 mm and a width on the same order as that of the interconnection substrate 10 so that the recess 16 for interconnection substrate is formed as shown in FIG. 5.

On the first common ink groove 5 of the first part 11a, the nipple opening 14 is formed so as to open in shape of a slot. The nipple opening 14 is formed so as to be connected to the ink supply pipe 12. A section extending from the nipple opening 14 to the ink supply pipe 12 is formed so as to have a gently tapering width.

The second part 11b of the manifold 11 is formed of a plate member having a thickness of 10 mm and made of aluminum, stainless steel, ceramic or the like. A top surface of the second part 11b is subjected to recess machining with a depth of 4 mm and with a width and a length as large as the widths of the piezoelectric substrate 1 so that the second common ink groove 6 is formed. On the second common ink groove 6 of the second part 11b, the nipple opening 15 is formed so as to open in shape of a slot. The nipple opening 15 is formed so as to be connected to the ink supply pipe 13. A section extending from the nipple opening 15 to the ink supply pipe 13 is formed so as to have a gently tapering width.

In the process of mounting the piezoelectric substrate 1 on the manifold 11, initially, the piezoelectric substrate 1 is bonded to the recess 17 for piezoelectric substrate of the first part 11a. According to the width and length of the recess 17 for the piezoelectric substrate that are as large as those of the piezoelectric substrate 1, the piezoelectric substrate 1 is fitted into the recess 17 for piezoelectric substrate, and bonding is carried out so that the interconnection substrate 10 is accommodated in the recess 16 for interconnection substrate formed on the boding surface 18 of the first part 11a. Consequently, a structure shown in FIG. 8 is obtained.

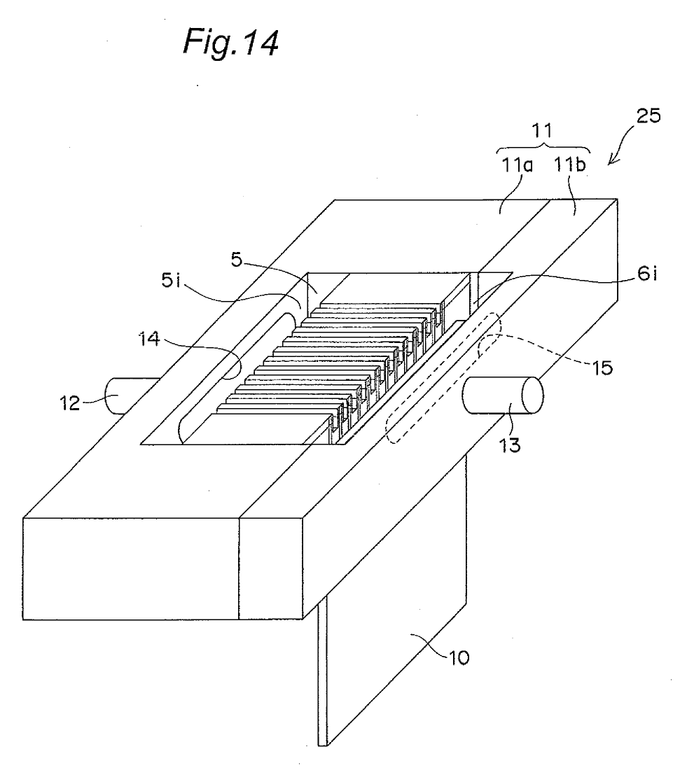

Then the second part 11b is bonded onto the boding surface 18 of the first part 11a. Consequently, a structure shown in FIG. 14 is obtained. The bonding has to be performed reliably so that the second common ink groove 6 can retain ink without leakage therethrough. On account of a possibility that the interconnection substrate 10 and the ACF 9 may be dissolved or swollen by the ink, preferably, a region in which the interconnection substrate 10 is connected to the electrode drawing parts 8 through the ACF 9 is sealed with adhesive so as to be protected against the ink. The adhesive is added into a gap between the piezoelectric substrate 1 and the recess 17 for piezoelectric substrate so as to seal the gap.

Subsequently, a process of bonding the nozzle plate will be described in which the nozzle plate 21 is bonded so as to cover the plurality of ink grooves 41 and the recess for common ink chambers so that the plurality of separated ink chambers 2 are formed from the plurality of ink grooves 41 and so that the first common ink chamber 5i and the second common ink chamber 6i are formed from the recess of the manifold 11. That is, the nozzle plate 21 having the nozzle holes 20 is bonded, from upside, onto the structure shown in FIG. 14. The nozzle plate 21 is bonded so as to spread across the piezoelectric substrate 1 and the manifold 11. After the nozzle plate 21 is bonded onto the piezoelectric substrate 1, adhesive is poured into a gap between the nozzle plate 21 and the manifold 11 so as to seal the gap. Thus the inkjet head 25 shown in FIG. 1 is finished. In the inkjet head 25 are formed the separated ink chambers 2, the first common ink chamber 5i, and the second common ink chamber 6i.

In the method for manufacturing the inkjet head of the embodiment, as described above, the inkjet head of the embodiment can easily be produced.

In FIG. 10 is shown an example of the machining of the grooves, which is preferably performed linearly so that the grooves penetrate the piezoelectric substrate 1 from one end to the other end thereof with a fixed depth. Though the description has been given on a single piezoelectric substrate 1, performing the linear machining with penetration through the piezoelectric substrate 51, into which the plurality of piezoelectric substrates 1 are gathered, from one end to the other end thereof includes performing the linear machining of the grooves with penetration through the plurality of piezoelectric substrates 1 from one end to the other end thereof in a lump.

The configuration in which the machining of the grooves is performed linearly so that the grooves penetrate the piezoelectric substrate 1 from one end to the other end thereof with the fixed depth is advantageous in that the machining of the grooves only requires movement of the rotating dicing blade 30 in a straight line without requiring the machining method with use of the vertical movement of the dicing blade 30, i.e., so-called chopper machining, and a special dicing machine.

In a configuration in which rounded portions with groove depths gradually decreasing are formed by transfer of a shape of outside diameter of the dicing blade to portions of ink grooves with the chopper machining using the vertical movement of the dicing blade 30 and in which shallow groove portions for forming external connection terminals are formed in connection with the rounded portions, the deeper driving portions of the ink grooves and the shallower the shallow groove portions, the larger lengths of the rounded portions. Besides, the larger the outside diameter of the dicing blade, the larger the lengths of the rounded portions. Eventually, the lengths have a great influence on number (what is called “yield per wafer”) of inkjet heads that can be obtained from one wafer-like piezoelectric substrate.

On assumptions of the depth of the ink grooves of 240 μm, the depth of the shallow groove portions of 5 μm, and the outside diameter of the blade of 25.4 mm, an area L to which the shape of the outside diameter of the blade is transferred is calculated by the following equation.

L=\sqrt{25.4²−(25.4−0.24)²}

L=3.48 mm [Equation 1]

A length of an area required for discharge from the inkjet head is assumed to be 3 mm. On further assumptions that the whole shallow groove portions are formed as the external connection terminals and that a length of the external connection terminals is 1 mm, a length of the inkjet head in a longitudinal direction of the ink grooves is 3.48+3+1=7.48 mm.

In this configuration, a proportion of the lengths of the rounded portions in the overall length of the one inkjet head is as follows.

(3.48+1)/7.48*100=about 60%

That is, the portions making no contribution to the discharge of ink make up about 60%.

The machining of the grooves on the piezoelectric substrate that is performed linearly so that the grooves penetrate the piezoelectric substrate 1 from one end to the other end thereof with the fixed depth as described above eliminates necessity of the area L=3.48 mm, to which the shape of the outside diameter of the blade is transferred, in a range of the piezoelectric substrate 1 corresponding to a size of a single inkjet head, and the mounting of the interconnection substrate 10 in an orientation perpendicular to the piezoelectric substrate 1 as shown in FIG. 4 eliminates necessity of the length for the external connection terminals, allowing a decrease by about 60% in the length of the inkjet head in total. The decrease in the length of the piezoelectric substrate required for manufacture of one inkjet head results in an increase in number of yielded inkjet heads per wafer and a decrease in cost per inkjet head.

In summary,

the inkjet head of the invention includes:

the manifold,

the piezoelectric substrate that is mounted on the manifold and that has the plurality of ink grooves separated from one another by the partition walls and provided with the electrodes on the inner walls thereof, and

the nozzle plate that is mounted on top of the partition walls of the piezoelectric substrate and that covers the upper side of the plurality of ink grooves so as to define the plurality of ink grooves as the plurality of separated ink chambers, wherein

the plurality of ink grooves are formed in parallel with one another so as to penetrate the piezoelectric substrate from one end to the other end thereof,

the manifold has the first common ink groove communicating with the plurality of separated ink chambers on one end side of the separated ink chambers and has the second common ink groove communicating with the plurality of separated ink chambers on the other end side of the separated ink chambers.

In the manifold having the first common ink groove communicating with the plurality of separated ink chambers on the one end side of the separated ink chambers and having the second common ink groove communicating with the plurality of separated ink chambers on the other end side of the separated ink chambers, accordingly, appropriate adjustment in widths, depths and the like of the first common ink groove and the second common ink groove can sufficiently decrease flow passage resistances of the first common ink groove and the second common ink groove in comparison with flow passage resistances of the separated ink chambers so that ink flow via the separated ink chambers in the inkjet head can easily be promoted. This has no influence on the number (what is called “yield per wafer”) of the inkjet heads that can be obtained from the one wafer-like piezoelectric substrate.

In short, the inkjet head can be provided that permits ink to be easily circulated therein and that is applicable to the ink containing fine particles, without making the structure thereof complicated.

In the inkjet head of the invention, the ink grooves are linearly formed with the fixed depth, and the bottom surfaces of the ink grooves are formed so as to parallel the bottom surface of the piezoelectric substrate.

Accordingly, the ink grooves that are linearly formed with the fixed depth and the bottom surfaces of the ink grooves that are formed so as to parallel the bottom surface of the piezoelectric substrate are advantageous in that the machining of the ink grooves only requires the movement of the rotating dicing blade in a straight line without requiring the machining method with use of the vertical movement of the dicing blade, i.e., so-called chopper machining, and a special dicing machine.

In the inkjet head of the invention, the nozzle plate is mounted so as to spread across the piezoelectric substrate and the manifold, covers the upper side of the first common ink groove so as to define the first common ink groove as the first common ink chamber, and covers the upper side of the second common ink groove so as to define the second common ink groove as the second common ink chamber.

By the nozzle plate that covers the upper side of the first common ink groove so as to define the first common ink groove as the first common ink chamber and that covers the upper side of the second common ink groove so as to define the second common ink groove as the second common ink chamber, the plurality of ink grooves, the first common ink groove, and the second common ink groove can simultaneously be covered so as to simultaneously define the plurality of separated ink chambers, the first common ink chamber, and the second common ink chamber, and thus efficiency of assembling works can be improved.

Among the plurality of separated ink chambers in the inkjet head of the invention, the separated ink chambers having the nozzle holes formed thereon are the discharge ink chambers, which are formed only of regions contributing to the discharge.

With the discharge ink chambers formed only of the regions contributing to the discharge, the nozzle holes can be formed corresponding to some desired ink grooves in response to the demands for decrease in nozzle hole density that have been caused by increase in size of liquid crystal screens.

Among the plurality of separated ink chambers in the inkjet head of the invention, the separated ink chambers having no nozzle holes formed thereon are the dummy ink chambers.

Since the separated ink chambers having no nozzle holes formed thereon, among the plurality of separated ink chambers, are the dummy ink chambers, the passage of ink through the dummy ink chambers can reduce the flow passage resistance of the plurality of separated ink chambers as a whole and can smooth the circulation of the ink even if sufficient sectional areas of the flow passages cannot be ensured and the flow passage resistance cannot be reduced only by the provision of the discharge ink chambers. As a result, the precipitation of the fine particles can be prevented and the number of the fine particles contained in each droplet being discharged can be stabilized.

The inkjet head of the invention has the first ink distribution mechanism for expelling all portions of ink supplied into the first common ink chamber, except a portion thereof that is to be consumed in the discharge from the separated common ink chambers, via the separated common ink chambers into the second common ink chamber.

The first ink distribution mechanism expels all the portions of the ink supplied into the first common ink chamber, except the portion thereof that is to be consumed in the discharge from the separated common ink chambers, via the separated common ink chambers into the second common ink chamber and is thus capable of positively producing ink flow passing through the separated ink chambers.

The inkjet head of the invention has the second ink distribution mechanism for expelling all portions of ink supplied into the second common ink chamber, except a portion thereof that is to be consumed in discharge from the separated common ink chambers, via the separated common ink chambers into the first common ink chamber.

The second ink distribution mechanism for expelling all the portions of the ink supplied into the second common ink chamber, except the portion thereof that is to be consumed in the discharge from the separated common ink chambers, via the separated common ink chambers into the first common ink chamber and is thus capable of positively producing ink flow passing through the separated ink chambers.

In the inkjet head of the invention, the electrodes formed on the inner walls of the ink grooves extend to side face parts of the piezoelectric substrate on which the separated ink chambers open.

Therefore, the electrodes extend to the side face parts of the piezoelectric substrate and thus can be formed by sputtering.

In the inkjet head of the invention, the electrodes extend to the only one side face part of the piezoelectric substrate.

Therefore, the electrodes extending to the only one side face part of the piezoelectric substrate have only to be formed on the one side face of the piezoelectric substrate and can be formed thereon by the electrode film formation on the substrate corresponding to two connected inkjet heads and later split thereof at the center part. This halves quantity of work in comparison with the electrode film formation on the separated piezoelectric substrates and improves work efficiency.

In the inkjet head of the invention, the electrodes are connected to the external connection substrate on the side face part of the piezoelectric substrate.

Thus the electrodes connected to the external connection substrate on the side face part of the piezoelectric substrate make it possible to thereby apply a voltage based on image data to the partition walls on both sides of each ink groove on the piezoelectric substrate and to drive the ink channels from outside.

The inkjet head manufacturing method of the invention includes steps of:

forming the plurality of ink grooves in parallel with one another by the groove machining on the piezoelectric substrate so that the grooves penetrate the piezoelectric substrate from one end to the other end thereof,

forming the conductor film as the electrodes on the piezoelectric substrate,

mounting the piezoelectric substrate on the manifold so as to form in the manifold the first common ink groove communicating with one end side of the plurality of ink grooves and the second common ink groove communicating with the other end side of the plurality of ink grooves, and

mounting the nozzle plate on the piezoelectric substrate and the manifold so as to cover the plurality of ink grooves, the first common ink groove, and the second common ink groove, thereby defining the ink grooves as the separated ink chambers, the first common ink groove as the first common ink chamber, and the second common ink groove as the second common ink chamber.

In the method including the steps of forming the ink grooves on the piezoelectric substrate, forming the electrodes on the piezoelectric substrate, mounting the piezoelectric substrate on the manifold so as to form in the manifold the first common ink groove and the second common ink groove, and mounting the nozzle plate on the piezoelectric substrate and the manifold so as to define the ink grooves as the separated ink chambers, the first common ink groove as the first common ink chamber, and the second common ink groove as the second common ink chamber, accordingly, appropriate adjustment in the widths, depths and the like of the first common ink groove and the second common ink groove can sufficiently decrease the flow passage resistances of the first common ink groove and the second common ink groove in comparison with the flow passage resistances of the separated ink chambers so that ink flow via the separated ink chambers in the inkjet head can easily be promoted. This has no influence on the number (what is called “yield per wafer”) of the inkjet heads that can be obtained from the one wafer-like piezoelectric substrate.

In short, the inkjet head can be provided that permits ink to be easily circulated therein and that is applicable to the ink containing fine particles, without making the structure thereof complicated.

In the inkjet head manufacturing method of the invention, the ink grooves are linearly formed with the fixed depth, and the bottom surfaces of the ink grooves are formed so as to parallel the bottom surface of the piezoelectric substrate.

Accordingly, the ink grooves that are linearly formed with the fixed depth and the bottom surfaces of the ink grooves that are formed so as to parallel the bottom surface of the piezoelectric substrate are advantageous in that the machining of the ink grooves only requires the movement of the rotating dicing blade in a straight line without requiring the machining method with use of the vertical movement of the dicing blade, i.e., so-called chopper machining, and a special dicing machine.

The invention is not limited to the embodiment described above. Though the nozzle holes are depicted so as to be small in number for convenience of description in the embodiment, for instance, the nozzle holes may be larger in number. A shape of the piezoelectric substrate 1 is not limited to the quadrangular shape but may be a circular shape or the like. The electrode drawing parts 8 may be provided on both opposite side face parts of the piezoelectric substrate 1.

1. An inkjet head comprising:
a manifold,
a piezoelectric substrate that is mounted in the manifold and that has a plurality of ink grooves separated from one another by partition walls and provided with electrodes on inner walls thereof, and
a nozzle plate that is mounted on top of the partition walls of the piezoelectric substrate and that covers upper side of the plurality of ink grooves so as to define the plurality of ink grooves as a plurality of separated ink chambers, wherein
the plurality of ink grooves are formed in parallel with one another so as to penetrate the piezoelectric substrate from one end to the other end thereof,
the manifold has a first common ink groove communicating with the plurality of separated ink chambers on one end side of the separated ink chambers and having a second common ink groove communicating with the plurality of separated ink chambers on the other end side of the separated ink chambers.

2. The inkjet head as claimed in claim 1, wherein
the ink grooves are linearly formed with a fixed depth, and wherein bottom surfaces of the ink grooves are formed so as to parallel a bottom surface of the piezoelectric substrate.

3. The inkjet head as claimed in claim 1, wherein
the nozzle plate is mounted so as to spread across the piezoelectric substrate and the manifold, covers upper side of the first common ink groove so as to define the first common ink groove as a first common ink chamber, and covers upper side of the second common ink groove so as to define the second common ink groove as a second common ink chamber.

4. The inkjet head as claimed in claim 1, wherein
separated ink chambers having nozzle holes formed thereon among the plurality of separated ink chambers are discharge ink chambers, and wherein
the discharge ink chambers are formed only of regions contributing to discharge.

5. The inkjet head as claimed in claim 4, wherein
separated ink chambers having no nozzle holes formed thereon among the plurality of separated ink chambers are dummy ink chambers.

6. The inkjet head as claimed in claim 3, comprising
a first ink distribution mechanism for expelling all portions of ink supplied into the first common ink chamber, except a portion thereof that is to be consumed in discharge from the separated common ink chambers, via the separated common ink chambers into the second common ink chamber.

7. The inkjet head as claimed in claim 3, comprising
a second ink distribution mechanism for expelling all portions of ink supplied into the second common ink chamber, except a portion thereof that is to be consumed in discharge from the separated common ink chambers, via the separated common ink chambers into the first common ink chamber.

8. The inkjet head as claimed in claim 1, wherein
the electrodes formed on the inner walls of the ink grooves extend to side face parts of the piezoelectric substrate on which the separated ink chambers open.

9. The inkjet head as claimed in claim 8, wherein
the electrodes extend to the only one side face part of the piezoelectric substrate.

10. The inkjet head as claimed in claim 8, wherein
the electrodes are connected to an external connection substrate on the side face part of the piezoelectric substrate.

11. A method for manufacturing an inkjet head, the method comprising steps of:
forming a plurality of ink grooves in parallel with one another by groove machining on a piezoelectric substrate so that the grooves penetrate the piezoelectric substrate from one end to the other end thereof,
forming a conductor film as the electrodes on the piezoelectric substrate,
mounting the piezoelectric substrate on a manifold so as to form in the manifold a first common ink groove communicating with one end side of the plurality of ink grooves and a second common ink groove communicating with the other end side of the plurality of ink grooves, and
mounting a nozzle plate on the piezoelectric substrate and the manifold so as to cover the plurality of ink grooves, the first common ink groove, and the second common ink groove, thereby defining the ink grooves as separated ink chambers, the first common ink groove as a first common ink chamber, and the second common ink groove as a second common ink chamber.

12. The inkjet head manufacturing method as claimed in claim 11, wherein
the ink grooves are linearly formed with a fixed depth, and wherein bottom surfaces of the ink grooves are formed so as to parallel a bottom surface of the piezoelectric substrate.
